(19) United States
(12) Patent Application Publication
(10) Pub. No.: US 2005/0087864 A1
(43) Pub. Date: Apr. 28, 2005

(54) Cavity-down semiconductor package with heat spreader

(75) Inventors: Ching-Hsu Yang, Taichung City (TW); Hong-Yuan Huang, Fengshan City (TW); Hsin-Fu Chuang, Ciaotou Township (TW); Chih-Huang Chang, Yongkang City (TW)

Correspondence Address: TROXELL LAW OFFICE PLLC, SUITE 1404, 5205 LEESBURG PIKE, FALLS CHURCH, VA, 22041, US

(73) Assignee: Advanced Semiconductor Engineering, Inc.

(21) Appl. No.: 11/006,675

(22) Filed: Dec. 8, 2004

(30) Foreign Application Priority Data
Sep. 12, 2003 (TW) 092134762

(51) Int. Cl. H01L 23/34

(52) U.S. Cl. 257/720

(57) ABSTRACT

A cavity-down semiconductor package mainly includes a heat spreader, a substrate, and a chip. The substrate has an outer surface, an inner surface opposing to the outer surface and an opening passing through the outer and inner surfaces. The inner surface is attached to the heat spreader to form a chip carrier with a chip cavity. The chip is located in the opening and electrically connected to the substrate. The substrate includes a metal cover layer over the inner surface. The metal cover layer can be bonded to the heat spreader to establish a thermal-coupling relationship to improve adhesion, heat conductibility and electrical performance between the substrate and the heat spreader.

### FIELD OF THE INVENTION

The present invention relates to a semiconductor package, more particularly to a thermally enhanced cavity-down semiconductor package for improving adhesion between heat spreader and substrate.

### BACKGROUND OF THE INVENTION

The known thermally enhanced cavity-down BGA package has excellent heat dissipation and a shorter electrically conductive path, in which a substrate with an opening is assembled with a heat spreader, and then a chip is accommodated in the opening of the substrate. The surface of the substrate is adhered to the heat spreader, and another surface of the substrate is placed with a plurality of solder balls. Several known cavity-down BGA packages have been disclosed in U.S. Patent Application Publication No. 2002/0195721 and U.S. Pat. No. 6,057,601.

The known opening substrate for cavity-down BGA package has an inner surface for attaching to the heat spreader and an outer surface for solder balls placement. Usually solder masks are formed over both inner and outer surfaces to protect traces inside the substrate from the contamination of solder paste, flux or dust. Normally there is adhesive resin between the inner solder mask of the substrate and the heat spreader. Because of the poor adhesion between the inner solder mask and the heat spreader and the poor moisture resistance of the adhesive resin, the substrate is easily separated from the heat spreader to cause delamination. The reliability of the package is seriously affected. Additionally, the thicker the resin adhesive layer is, the larger the thermal resistance is formed between the substrate and the heat spreader. That will lead to heat accumulation inside the substrate.

### SUMMARY

It is a primary object of the present invention to provide a cavity-down semiconductor package, including a heat spreader, a substrate with opening and a chip in the opening. A metal cover layer is formed over the inner surface of the substrate for attaching to the heat spreader. The metal cover layer is bonded to the heat spreader to establish a thermal-coupling relationship so as to replace the inner solder mask on the substrate and the ground layer inside the substrate to enhance substrate adhesion and improve substrate heat dissipation and substrate grounding capabilities.

It is a secondary object of the present invention to provide a cavity-down semiconductor package, which utilizes electrical vias of the substrate to electrically connect the metal cover layer on the substrate. The metal cover layer is formed over the inner surface of the substrate to attach to the heat spreader to simplify the traditional grounding structure.

It is a third object of the present invention to provide a chip carrier for cavity-down semiconductor package, which includes a heat spreader and an opening substrate with a metal cover layer. The metal cover layer, which may be formed by electroplating, sputtering or lamination, is formed over the inner surface of the substrate to attach to the heat spreader and to serve as an exposed ground layer of the substrate for replacing the solder mask on the inner surface of a substrate and the traditional ground layer inside a substrate to improve heat dissipation, electrical connection and grounding efficiencies between the substrate and the heat spreader.

The cavity-down semiconductor package in accordance with the present invention mainly includes a heat spreader, a substrate, a chip and an encapsulant. The substrate has an outer surface, an inner surface and an opening. A solder mask is formed over the outer surface, and a plurality of connecting pads are exposed out of the solder mask. A metal cover layer is formed over the inner surface. The inner surface of the substrate is attached to the heat spreader, the metal cover layer is bonded to the heat spreader to establish a thermal-coupling relationship. Eutectic bonding for the metal cover layer is preferred. A chip carrier with a chip cavity consists of the opening substrate and the heat spreader for accommodating a chip. Back surface of the chip is located inside the opening and electrically connected to the substrate. The encapsulant seals the opening of the substrate and covers the chip. Therefore, the metal cover layer over the inner surface of the substrate can serve as a surface protecting layer, a surface bonding layer, a thermal-coupling layer and a ground layer for the substrate to enhance the adhesion between the substrate and the heat spreader and improve heat conductibility and electrical performance of the substrate.

### DESCRIPTION OF THE DRAWINGS

FIG. 1 is a cross-sectional view of a cavity-down semiconductor package in accordance with the present invention.

FIG. 2 is a partially cross-sectional view of the cavity-down semiconductor package in accordance with the present invention.

### DETAILED DESCRIPTION OF THE PRESENT INVENTION

Referring to the drawings attached, the present invention is described by means of the embodiment(s) below.

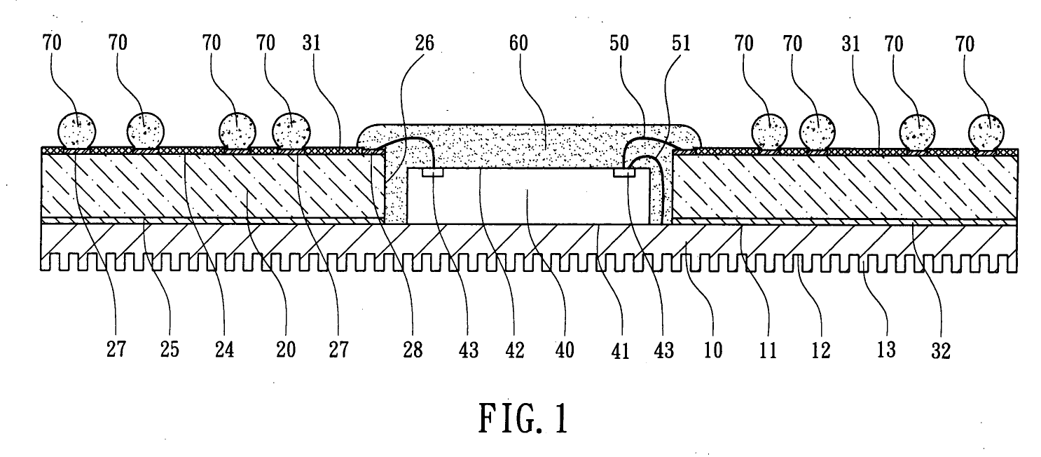

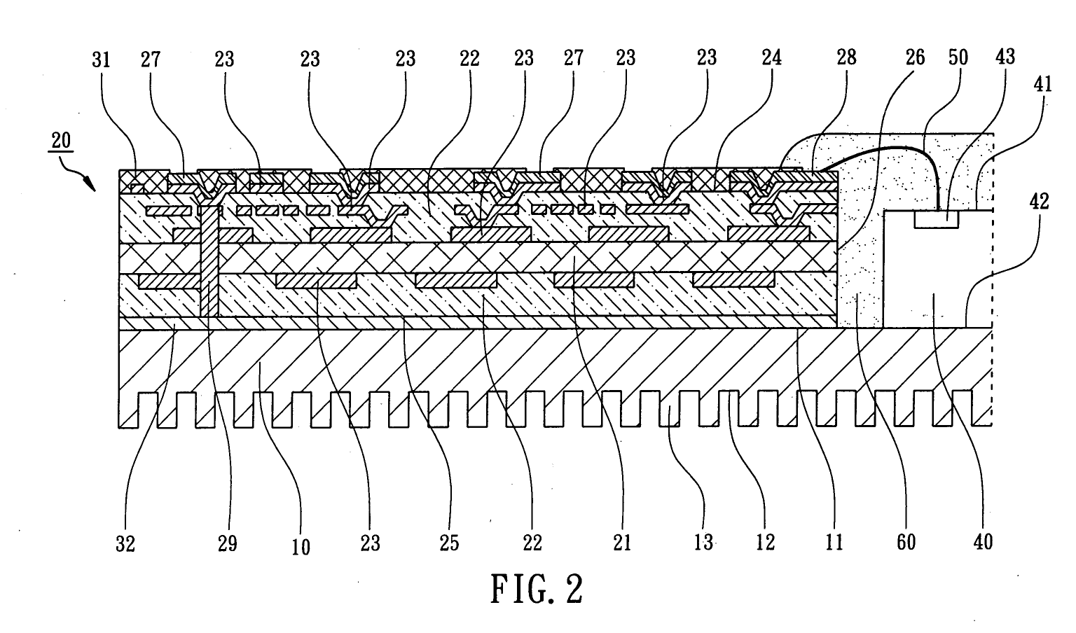

Referring to FIGS. 1 and 2, a cavity-down semiconductor package according to the embodiment of the present invention mainly comprises a heat spreader 10, a substrate 20, a chip 40 and an encapsulant 60. The heat spreader 10 is made of metal with excellent heat conduction and has a first surface 11 and a second surface 12. The first surface 11 of the heat spreader 10 may be utilized to attach to the substrate 20 for carrying the chip 40, and the second surface 12 of the heat spreader 10 may serve as a heat-dissipating surface. In this embodiment, the second surface 12 can be formed with a plurality of heat fins 13 to increase the efficiency of heat dissipation.

The substrate 20 is attached to the heat spreader 10 and has wiring pattern(s) inside, such as printed circuit board, ceramic circuit board or flexible substrate, for the electrical transmission of the chip 40. In this embodiment, the substrate 20 is a build-up PCB. Referring to FIG. 2, the substrate 20 includes a core layer 21 made of glass fiber reinforced resin, at least a dielectric layer 22 and at least a layer of wiring pattern 23. The substrate 20 has an outer surface 24, an inner surface 25 and an opening 26. A cavity for accommodating the chip 40 is formed by the opening 26 of the substrate 20 and the first surface 11 of the heat spreader 10. The outer surface 24 of the substrate 20 serves as a surface-mounting surface of the package. A solder mask 31 is formed over the outer surface 24 of the substrate 20 and has a plurality of openings to expose a plurality of connecting pads 27 on the outer surface 24 for ball placement. In this embodiment, a plurality of wire-bonding fingers 28 are also formed on the outer surface 24. The wire-bonding fingers 28 are arranged around the opening 26, which may be formed from one inner wiring layer of the substrate 20 (not showed in the drawings), and are electrically connected with the corresponding connecting pads 27 by the wiring pattern 23 of the substrate 20 for wire-bonding connection with the chip 40. The connecting pads 27 are arranged in an array to dispose the solder balls 70, pins or other electrically connecting components. A metal cover layer 32 is formed over the inner surface 25 of the substrate 20, at least 80% area of the inner surface 25, and more preferably it completely covers the inner surface 25. The metal cover layer 32 is directly attached to the first surface 11 of the heat spreader 10 to establish a thermal-coupling relationship between the substrate 20 and the heat spreader 10. The metal cover layer 32 is selected from the group consisting of an electroplating layer, a sputtering layer and a laminated metal foil, and includes copper, lead, tin, aluminum, silver, nickel/gold or a combination of the metals mentioned-above by electroplating, sputtering, or lamination. In this embodiment, the inner surface 25 of the substrate 20 is free from solder mask and adhesive resin. Preferably, the metal cover layer 32 on the substrate 20 is eutectic bonded to the heat spreader 10 so as to become a very thin eutectic layer which can firmly connect the heat spreader 10 with excellent heat conductibility. Therefore, the metal cover layer 32 over the inner surface 25 is utilized as a surface protection layer, a surface bonding layer and a heat-conducting layer for the substrate 20. It is preferable that a silver layer or a gold layer are formed on the first surface 11 of the heat spreader 10 in advance for the eutectic bonding. Moreover, the metal cover layer 32 may include copper or tin to enhance the eutectic bonding to the heat spreader 10. Therefore, the substrate 20 can be assembled with the heat spreader 10 to form a chip carrier with a cavity which is suitable for cavity-down semiconductor package. The metal cover layer 32 formed over the inner surface 25 of the substrate is utilized for bonding the heat spreader 10 to replace the traditional solder mask and adhesive resin on the inner surface 25 of the substrate 20 to improve adhesion and heat dissipation between the substrate 20 and the heat spreader 10. Besides, the substrate 20 may have at least an electrical via 29 to electrically connect with the metal cover layer 32. Thus, the metal cover layer 32 formed over the inner surface 25 can serve as an exposed ground layer for the substrate 20 to replace the traditional ground layer having signal-insulating holes inside the substrate 20.

The chip 40 has an active surface 41 with a plurality of bonding pads 43 and a back surface 42. The chip 40 is located in the opening 26 of the substrate 20. The back surface 42 of the chip 40 is attached to the central exposed region of the first surface 11 of the heat spreader 10. Preferably, the chip 40 is also eutectic bonded to the heat spreader 10. A plurality of bonding wires 50 or known electrically connecting components connect the bonding pads 43 of the chip 40 with the wire-bonding fingers 28 of the substrate 20 so that the chip 40 is electrically connected to the connecting pads 27 of the substrate 20 and the heat spreader 10. In this embodiment, a ground bonding wire 51 is utilized for electrically connecting the ground bonding pad (not showed in the drawings) of the chip 40 with the heat spreader 10 or the metal cover layer 32 so as to electrically connect the electrical via 29 of the substrate 20. The encapsulant 60 is formed by molding or dispensing to seal the opening 26 of the substrate 20 and cover the chip 40 and the bonding wires 50, 51. Preferably, a plurality of solder balls 70 can be further placed on the connecting pads 27 on the outer surface 24 of the substrate 20 to complete a cavity-down BGA package. Therefore, according to the present invention the metal cover layer 32 formed over the inner surface 25 of the substrate 20 can serve as a surface protecting layer, a surface adhering layer, a heat conducting layer and a ground layer to improve adhesion between the substrate 20 and the heat spreader 10, heat conductibility and electrical performance of the substrate 20. The cavity-down semiconductor package has a thinner thickness and a better reliability.

While the present invention has been particularly illustrated and described in detail with respect to the preferred embodiments thereof, it will be clearly understood by those skilled in the art that various changed in form and details may be made without departing from the spirit and scope of the present invention.

1. A cavity-down semiconductor package comprising:
a heat spreader;
a substrate having an outer surface, an inner surface and an opening passing through the outer and inner surfaces, the substrate including a solder mask formed over the outer surface, a plurality of connecting pads on the outer surface, and a metal layer formed over the inner surface, the metal layer being attached to the heat spreader;
a chip located in the opening of the substrate and electrically connected to the connecting pads of the substrate; and
an encapsulant sealing the opening of the substrate to cover the chip.

2. The semiconductor package in accordance with claim 1, wherein the metal layer is directly attached to the heat spreader.

3. The semiconductor package in accordance with claim 1, wherein the metal layer is eutectic bonded to the heat spreader.

4. The semiconductor package in accordance with claim 1, wherein the chip is eutectic bonded to the heat spreader.

5. The semiconductor package in accordance with claim 1, wherein the substrate has at least an electrical via electrically connecting the metal layer.

6. The semiconductor package in accordance with claim 5, wherein the metal layer is a ground layer.

7. The semiconductor package in accordance with claim 2, wherein the metal layer includes copper or tin.

8. The semiconductor package in accordance with claim 2, wherein the heat spreader has a plating layer for eutectic bonding of the metal layer.

9. The semiconductor package in accordance with claim 1, further comprising a plurality of bonding wires connecting the chip with the substrate.

10. The semiconductor package in accordance with claim 9, further comprising at least a ground bonding wire electrically connecting a ground pad of the chip to the heat spreader or the metal layer.

11. The semiconductor package in accordance with claim 1, further comprising a plurality of solder balls disposed on the connecting pads of the substrate, the connecting pads being arranged in an array on the outer surface of the substrate.

12. The semiconductor package in accordance with claim 1, wherein the heat spreader has a plurality of heat fins.

13. The semiconductor package in accordance with claim 1, wherein the metal layer is selected from the group consisting of an electroplating layer, a sputtering layer and a laminated metal foil.

14. A chip carrier for a cavity-down semiconductor package, comprising:
a heat spreader; and
a substrate having an outer surface, an inner surface and an opening passing through the outer and inner surfaces, the substrate including a plurality of connecting pads on the outer surface, and a metal layer formed over the inner surface, the metal layer being directly bonded to the heat spreader.

15. The chip carrier in accordance with claim 14, wherein the metal layer is eutectic bonded to the heat spreader.

16. The chip carrier in accordance with claim 14, wherein the substrate has at least an electrical via electrically connecting the metal layer.

17. The chip carrier in accordance with claim 16, wherein the metal layer is a ground layer.

18. The chip carrier in accordance with claim 14, wherein the metal layer is selected from one the group consisting of an electroplating layer, a sputtering layer and a laminated metal foil.

19. The chip carrier in accordance with claim 14, wherein the heat spreader has a plurality of heat fins.
